(19) United States
(12) Patent Application Publication
(10) Pub. No.: US 2011/0265710 A1
(43) Pub. Date: Nov. 3, 2011

(54) FILM FORMING APPARATUS AND METHOD

(76) Inventors: Kunihiko Suzuki, Shizuoka (JP); Shinichi Mitani, Shizuoka (JP); Toshiro Tsumori, Kanagawa (JP)

(21) Appl. No.: 13/096,349

(22) Filed: Apr. 28, 2011

(30) Foreign Application Priority Data
Apr. 30, 2010 (JP) 2010-104903

(51) Int. Cl. C30B 23/06

(52) U.S. Cl. 117/85; 118/712

(57) ABSTRACT

A film-forming apparatus includes a chamber in which a substrate is to be placed, a reaction gas supply portion that supplies a reaction gas into the chamber, a heater that heats the substrate, a radiation thermometer that is provided outside the chamber to measure the temperature of the substrate by receiving radiant light from the substrate, and a tubular member that protects an optical path of radiant light between the substrate and the radiation thermometer. An inert gas is supplied from an inert gas supply portion to the tubular member. The tubular member preferably has an inner peripheral surface and an outer peripheral surface made of a material having a lower emissivity than the inner peripheral surface.

### CROSS-REFERENCE TO RELATED APPLICATION

The entire disclosure of a Japanese Patent Application No. 2010-104903, filed on Apr. 30, 2010 including specification, claims, drawings and summary, on which the Convention priority of the present application is based, are incorporated herein.

### FIELD OF THE INVENTION

### Background

The present invention relates to a film-forming apparatus and a film-forming method.

An epitaxial growth technique is conventionally used to manufacture semiconductor devices requiring relatively thick crystalline films such as power devices (e.g., IGBTs (Insulated Gate Bipolar Transistors).

In the case of a vapor-phase epitaxial method used for epitaxial growth, a film-forming chamber, in which a substrate is placed to form an epitaxial film thereon, is maintained at atmospheric pressure or reduced pressure. When a reaction gas is supplied into the film-forming chamber while the substrate is heated, the thermal decomposition reaction or hydrogen reduction reaction of the reaction gas occurs on the surface of the substrate so that a vapor-phase epitaxial film is formed on the substrate.

In order to manufacture thick epitaxial wafers with high yield, it is necessary to increase a film-forming rate by bringing the surfaces of uniformly-heated wafers into contact with a fresh reaction gas one after another. For example, in the case of a conventional film-forming apparatus, epitaxial growth is performed while a wafer is rotated at high speed (see, for example, Japanese Patent Application Laid-Open No. 2008-108983).

FIG. 2 is a schematic sectional view showing the structure of a conventional film-forming apparatus using an epitaxial growth technique.

In FIG. 2 showing a film-forming apparatus 200, the reference numeral 201 represents a film-forming chamber, the reference numeral 202 represents a hollow tubular liner that covers and protects the inner wall of the chamber, the reference numerals 203a and 203b represent flow paths through which cooling water flows to cool the chamber, the reference numeral 204 represents a supply portion that introduces a reaction gas 225, the reference numeral 205 represents a gas discharge portion that discharges the reaction gas 225 that has been subjected to reaction, the reference numeral 206 represents a substrate, such as a wafer, on which an epitaxial film is to be formed by vapor-phase epitaxy, the reference numeral 207 represents a susceptor that supports the substrate 206, the reference numeral 208 represents a heater that is supported by a support (not shown) to heat the substrate 206, the reference numeral 209 represents a flange portion that connects upper and lower sections of the chamber 201 with each other, the reference numeral 210 represents a gasket that seals the flange portion 209, the reference numeral 211 represents a flange portion that connects the gas discharge portion 205 with a pipe, and the reference numeral 212 represents a gasket that seals the flange portion 211.

The liner 202 includes a head section 231 and a body section 230, and a shower plate 220 is attached to the head section 231 of the liner 201. The shower plate 220 is a gas straightening vane having the function of uniformly supplying the reaction gas 225 onto the surface of the substrate 206.

In the case of the film-forming apparatus 200, the substrate 206 is heated by the heater 208 while being rotated. In this state, the reaction gas 225 is supplied from the supply portion 204 into the chamber 201 through through-holes 221 of the shower plate 220. The head section 231 of the liner 202 has an inner diameter smaller than that of the body section 230 of the liner 202 in which the susceptor 207 is placed. The reaction gas 225 flows downward toward the surface of the substrate 206 through the head section 231.

When the reaction gas 225 reaches the surface of the substrate 206, a thermal decomposition reaction or a hydrogen reduction reaction occurs so that a crystalline film is formed on the surface of the substrate 206. At this time, part of the reaction gas that has not been used for the vapor-phase epitaxial reaction is altered and discharged as a produced gas together with the reaction gas 225 from the gas discharge portion 205 provided in the lower section of the chamber 201 as the need arises.

The flange portion 209 of the chamber 201 is sealed with the gasket 210, and the flange portion 211 of the gas discharge portion 205 is sealed with the gasket 212. The flow paths 203a and 203b for circulating cooling water are provided in and around the periphery of the chamber 201 to prevent the thermal deterioration of the gaskets 210 and 212 (which will be described later).

In the case of the film-forming apparatus 200, there is a case where the substrate 206 is heated to a high temperature exceeding 1000° C. by the heater 208 during vapor-phase film growth. Further, there is also a case where the substrate 206 needs to be heated to a high temperature of 1500° C. or higher depending on the type of epitaxial film to be formed.

For example, SiC (silicon carbide) has an energy gap two to three times larger than that of a conventional semiconductor material such as Si (silicon) or GaAs (gallium arsenide), and has a breakdown electric field about one order of magnitude higher than that of such a conventional semiconductor material. Therefore, SiC is a semiconductor material expected to be used in high-voltage power semiconductor devices. In order to obtain a SiC monocrystalline substrate by epitaxial growth of such SiC, a substrate needs to be heated to 1500° C. or higher.

The surface temperature of the substrate 206 is measured by a radiation thermometer 226 provided in the upper section of the chamber 201. This is because since the substrate 206 is rotated during film growth, a thermocouple is not suitable for the measurement of the surface temperature of the substrate 206.

A specific example of the radiation thermometer 226 includes a fiber radiation thermometer for use under high temperature conditions (see Japanese Patent No. 2770065). The thermometer includes an optical lens that focuses radiant light emitted from a measurement object, an optical fiber that transmits radiant light focused by the optical lens to a temperature conversion unit, a lens holder that holds the optical lens, a light-receiving portion case that supports and fixes the end face of the optical fiber, and a temperature conversion unit that measures the temperature of a measurement object based on the intensity of light transmitted by the optical fiber.

In the case of the film-forming apparatus 200, the shower plate 220 is made of transparent quartz, and therefore radiant light from the substrate 206 can pass through the shower plate 220 and be received by the radiation thermometer 226. Temperature data measured by the radiation thermometer 226 is sent to a control system (not shown), and is then fed back to control the output of the heater 208. This makes it possible to heat the substrate 206 to a desired temperature.

As described above, in order to obtain a SiC monocrystalline substrate by growing SiC crystal on the substrate 206, the substrate 206 needs to be heated to a very high temperature.

However, when the substrate 206 is heated to such a high temperature by the heater 208, radiation heat from the heater 208 increases not only the temperature of the substrate 206 but also the temperatures of other members constituting the film-forming apparatus 200. This phenomenon particularly occurs in members located near high-temperature areas such as the substrate 206 and the heater 208 and in the inner wall of the chamber 201.

When the reaction gas 225 comes into contact with such high-temperature areas appearing in the chamber 201, the thermal decomposition reaction of the reaction gas 225 occurs also in the high-temperature areas as in the case where the reaction gas 225 comes into contact with the surface of the substrate 206 heated to a high temperature.

For example, in order to form a SiC epitaxial film on the surface of a wafer, a mixed gas, prepared by mixing, for example, silane (SiH₄) as a Si source, propane (C₃H₈) as a C source, and hydrogen gas as a carrier gas is used as the reaction gas 225. The reaction gas 225 is supplied from the supply portion 204 provided in the upper section of the chamber 201 into the chamber 201, and is decomposed when reaching the surface of the substrate 206, which has been heated to a high temperature.

However, the reaction gas 225 having the above composition is highly reactive, and therefore even when the reaction gas 225 comes into contact with members provided in the chamber 201 other than the substrate 206, the decomposition reaction of the reaction gas 225 occurs as long as the members satisfy certain temperature conditions. As a result, crystalline grains derived from the reaction gas 225 are adhered to the members in the chamber 201. When the crystalline grains are adhered to the shower plate 220, radiant light emitted from the substrate 206 heated to a high temperature cannot be received by the radiation thermometer 226. In this case, there is a fear that the temperature of the substrate 206 is judged to be lower than the actual temperature of the substrate 206 so that the output of the heater 208 becomes excessive.

In view of the above circumstances, it is an object of the present invention to provide a film-forming apparatus and a film-forming method that can achieve accurate contactless measurement of the temperature of a substrate.

Other challenges and advantages of the present invention are apparent from the following description.

### SUMMARY OF THE INVENTION

In one aspect of the present invention, a film-forming apparatus comprising: a film-forming chamber in which a substrate is to be placed; a flow path through which a reaction gas is to be supplied into the film-forming chamber; a heating unit that heats the substrate; a radiation thermometer that is provided outside the film-forming chamber to measure a temperature of the substrate by receiving radiant light from the substrate; and a member that protects the passage of optical path of the radiant light between the substrate and the radiation thermometer.

In another aspect of the present invention, a film-forming method comprising: introducing a reaction gas into a film-forming chamber, in which a substrate is being heated, to perform film formation, wherein a radiation thermometer is provided outside the film-forming chamber, an optical path of radiant light emitted from the substrate and received by the radiation thermometer is covered with a tubular member, and a temperature of the substrate is measured based on an light intensity of the radiant light received by the radiation thermometer.

### BRIEF DESCRIPTION OF THE DRAWINGS

FIG. 1 is a schematic sectional view of a film-forming apparatus according to the present invention.

FIG. 2 is a schematic sectional view of a conventional film-forming apparatus.

### DETAILED DESCRIPTION OF EMBODIMENTS

Hereinbelow, a film-forming apparatus and a film-forming method according to an embodiment of the present invention will be described with reference to a case where a SiC film is formed. However, the present invention is not limited thereto and can be applied also to an apparatus and a method for forming another film such as a Si film.

### First Embodiment

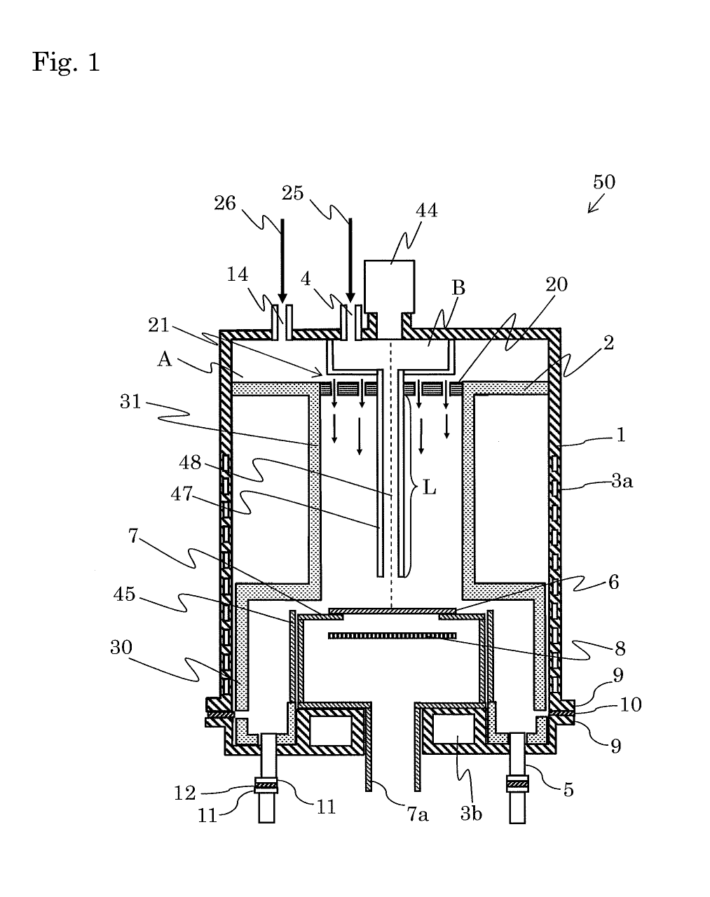

FIG. 1 is a schematic sectional view of a film-forming apparatus according to this embodiment. A film-forming apparatus 50 shown in FIG. 1 can be used to form a SiC film. In this case, a SiC wafer can be used as a substrate 6. However, the substrate 6 is not limited thereto, and in some cases, may be a wafer made of another material. For example, a Si wafer, another insulating substrate such as SiO₂ (quartz), or a semi-insulating substrate such as high-resistance GaAs may be used instead of the SiC wafer.

The film-forming apparatus 50 includes a chamber 1 as a film-forming chamber, a hollow tubular liner 2 that covers and protects the inner wall of the chamber 1, flow paths 3a and 3b through which cooling water flows to cool the chamber 1, an inert gas supply portion 4 for introducing an inert gas 25 into the film-forming apparatus 50, a reaction gas supply portion 14 for introducing a reaction gas 26, a gas discharge portion 5 that discharges the reaction gas 26 that has been subjected to reaction, a susceptor 7 that supports the substrate 6 placed thereon, a heater 8 that is supported by a support (not shown) to heat the substrate 6, a flange portion 9 that connects upper and lower sections of the chamber 1 with each other, a gasket 10 that seals the flange portion 9, a flange portion 11 that connects the gas discharge portion 5 with a pipe, and a gasket 12 that seals the flange portion 11.

The liner 2 is made of a material having very high heat resistance. For example, a member formed by coating carbon with SiC can be used. The liner 2 includes a head section 31 having an opening, and a shower plate 20 is attached to the opening of the head section 31. The shower plate 20 is a gas straightening vane for uniformly supplying the reaction gas 26 onto the surface of the substrate 6. The shower plate 20 has a plurality of through holes 21 for supplying the reaction gas 26.

It is to be noted that the reason for providing the liner 2 is that the wall of the chamber of the film-forming apparatus is generally made of stainless steel. That is, the liner 2 is used to cover the entire surface of the wall, made of stainless steel of the film-forming apparatus 50 so that the wall is not exposed to a vapor-phase reaction system. The liner 2 has the effect of preventing adhesion of particles to the wall of the chamber 1 or contamination of the wall of the chamber 1 with metal during the formation of a crystalline film and the effect of preventing erosion of the wall of the chamber 1 by the reaction gas 26.

The liner 2 is hollow and tubular and includes a body section 30 in which the susceptor 7 is placed and the head section 31 having an inner diameter smaller than that of the body section 30. In the body section 30, the susceptor 7 is placed, and the substrate 6 is placed on the susceptor 7. When a SiC film is formed, the substrate 6 is rotated at high speed by rotating the susceptor 7. As described above, the shower plate 20 is provided in the upper opening of the head section 31 of the liner 2. The shower plate 20 is used to uniformly supply the reaction gas 26 onto the surface of the substrate 6 placed on the susceptor 7 placed in the body section 30.

The inner diameter of the head section 31 of the liner 2 is determined depending on the arrangement of the through holes 21 of the shower plate 20 and the size of the substrate 6. This makes it possible to reduce wasted space where the reaction gas 26 supplied through the through holes 21 of the shower plate 20 is diffused. That is, the film-forming apparatus 50 is configured so that the reaction gas 26 supplied through the shower plate 20 can be efficiently and economically converged on the surface of the substrate 6. Further, the film-forming apparatus 50 is configured so that the gap between the periphery of the substrate 6 and the liner 2 is minimized to allow the reaction gas 26 to flow more uniformly onto the surface of the substrate 6.

By forming the liner 2 into the shape described above, it is possible to allow a vapor-phase epitaxial reaction to efficiently proceed on the surface of the substrate 6. More specifically, the flow of the reaction gas 26 supplied from the reaction gas supply portion 14 is straightened by allowing the reaction gas 26 to pass through the through holes 21 of the shower plate 20 so that the reaction gas 26 flows substantially vertically downward toward the substrate 6 placed under the shower plate 20. That is, the reaction gas 26 forms a so-called vertical flow. Then, the reaction gas 26 is attracted to the substrate 6 by the attracting effect of the substrate 6 rotating at high speed, and comes into collision with the substrate 6, and then flows in substantially laminar flow in a horizontal direction along the upper surface of the substrate 6 without forming a turbulent flow. In this way, a high-quality epitaxial film with high thickness uniformity is formed by straightening the flow of the reaction gas 26 that flows toward the surface of the substrate 6.

A reflector 45 is vertically provided at the bottom of the liner 2 so as to surround the susceptor 7, on which the substrate 6 is to be placed, and the heater 8. The reflector 45 reflects heat from the heater 8 to enhance the efficiency of heating the substrate 6 placed on the susceptor 7 and to inhibit an excessive increase in the temperatures of, for example, the components of the film-forming apparatus 50 located around the substrate 6 and the heater 8.

As described above, the film-forming apparatus 50 shown in FIG. 1 uses the gasket 10 for sealing the flange portion 9 of the chamber 1 and the gasket 12 for sealing the flange portion 11 of the gas discharge portion 5. These gaskets 10 and 12 are preferably made of fluorine-containing rubber and have an allowable temperature limit of about 300° C. In the case of this embodiment, the flow paths 3a and 3b through which cooling water flows to cool the chamber 1 are provided to prevent thermal degradation of the gaskets 10 and 12.

As for the heater 8, a resistance heating-type heater made of a SiC material is used.

As described above, the substrate 6 is placed on the susceptor 7. The susceptor 7 is connected to a rotating mechanism (not shown) via a susceptor support 7a. During a vapor-phase epitaxial reaction, the substrate 6 placed on the susceptor 7 is rotated at high speed by rotating the susceptor 7.

For example, in order to form a SiC epitaxial film on the substrate 6, a mixed gas obtained by mixing a silicon (Si) source gas such as silane (SiH₄) or dichlorosilane (SiH₂Cl₂), a carbon (C) source gas such as propane (C₃H₈) or acetylene (C₂H₂), and hydrogen (H₂) gas as a carrier gas is used as the reaction gas 26. The mixed gas is introduced from the reaction gas supply portion 14 through the through holes 21 of the shower plate 20 into the chamber 1. The reaction gas 26 supplied into the chamber 1 is used in a reaction for forming a SiC epitaxial film. More specifically, a thermal decomposition reaction or a hydrogen reduction reaction occurs on the surface of the substrate 6 so that a desired crystalline film is formed on the surface of the substrate 6. Part of the reaction gas 26 that has not been used in the vapor-phase epitaxial reaction is altered and discharged as a produced gas from the gas discharge portion 5 provided in the lower section of the chamber 1.

It is to be noted that a hydrogen gas supply portion (not shown) for supplying hydrogen gas as a carrier gas into the chamber 1 may be further provided in the upper section of the chamber 1 separately from the reaction gas supply portion 14. In this case, a gas containing a carbon (C) source gas (e.g., acetylene) is supplied from the reaction gas supply portion 14 and hydrogen gas as a carrier gas is supplied from the hydrogen gas supply portion, and these gases are mixed in the chamber 1 and supplied onto the surface of the substrate 6.

The surface temperature of the substrate 6 changed by heating is measured by a radiation thermometer 44 provided in the upper section of the chamber 1 shown in FIG. 1. The radiation thermometer 44 is a thermometer for contactless measurement of the temperature of the substrate 6 based on radiant light from the substrate 6 placed in the chamber 1. The structure of the radiation thermometer 44 is not shown, but the radiation thermometer 44 includes a condensing lens that focuses radiant light from the substrate 6 as a measurement object on the end face of an optical fiber, an optical fiber that transmits radiant light focused by the condensing lens to a temperature measurement unit, a temperature measurement unit that measures the temperature of the substrate 6 based on the light intensity of radiant light transmitted by the optical fiber, and a lens holder that supports the end face of the optical fiber and the condensing lens as components. The temperature measurement unit includes a filter that transmits light of a predetermined wavelength out of light transmitted by the optical fiber, a photoelectric conversion element that converts light that has passed through the filter into an electric signal, and a temperature calculation unit that calculates the temperature of a measurement object based on an electric signal obtained by photoelectric conversion.

Temperature measurement using the radiation thermometer 44 is performed in the following manner.

During epitaxial film growth, the substrate 6 as a measurement object is placed on the susceptor 7 placed in the chamber 1. In the process of the epitaxial film growth, radiant light of continuous wavelength is emitted from the substrate 6 based on Planck's radiation law by heating the substrate 6 to a high temperature.

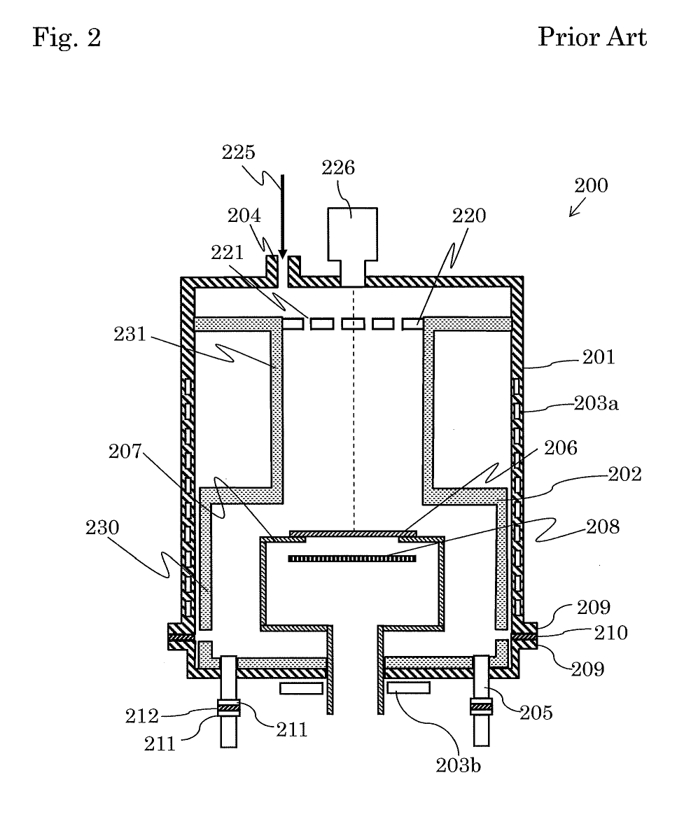

In the case of a conventional film-forming apparatus 200 shown in FIG. 2, part of radiant light emitted from a substrate 206 passes through a shower plate 220 made of transparent quartz and is focused by a condensing lens on the end face of an optical fiber. The radiant light focused by the condensing lens is transmitted by the optical fiber and filtered, and then radiant light of a predetermined wavelength is selectively received by a photoelectric conversion element. The photoelectric conversion element converts the radiant light into an electric signal, and the temperature of the substrate 206 is measured based on the intensity of the electric signal.

However, when crystalline grains derived from a reaction gas 225 are adhered to the shower plate 220 of the film-forming apparatus 200, radiant light emitted from the substrate 206 heated to a high temperature cannot be received by a radiation thermometer 226. In this case, there is a fear that the temperature of the substrate 206 is judged to be lower than the actual temperature of the substrate 206 so that the output of the heater 208 becomes excessive.

On the other hand, as shown in FIG. 1, the film-forming apparatus 50 according to this embodiment is provided with a tubular member 47. The tubular member 47 is a member that protects the passage of an optical path 48 of radiant light emitted from the substrate 6. It is to be noted that the tubular member 47 used in this embodiment is not limited as long as it can protect the optical path 48, and therefore a member having a shape other than tubular or a combination of a tubular member and a member having a shape other than tubular may be used.

The end of the tubular member 47 on the radiation thermometer 44 side is connected to a space B separated from a flow path A of the reaction gas 26. The space B is connected to the inert gas supply portion 4, and therefore the inert gas 25 supplied from the inert gas supply portion 4 flows downward through the tubular member 47 toward the substrate 6. Examples of the inert gas include nitrogen (N₂) gas, helium (He) gas, and argon (Ar) gas. Alternatively, hydrogen (H₂) gas may be used instead of the inert gas.

By providing the tubular member 47, the optical path 48 of radiant light can be secured. This makes it possible to prevent radiant light emitted from the substrate 6 toward the radiation thermometer 44 from being cut off by crystalline grains derived from the reaction gas 26. Further, by separating the flow path of the inert gas 25 from the flow path of the reaction gas 26 so that the inert gas 25 can flow downward through the tubular member 47 toward the substrate 6, it is possible to prevent the reaction gas 26 supplied into the chamber 1 from entering the inside of the tubular member 47 to prevent the optical path of radiant light from being blocked by grains adhered to the inner wall of the tubular member 47.

Unlike the conventional film-forming apparatus 200, the film-forming apparatus according to this embodiment has such a structure as described above, and therefore the shower plate 20 does not need to be made of transparent quartz. This is advantageous for forming a SiC film. In order to obtain a SiC monocrystalline substrate by epitaxial growth of SiC, it is necessary to increase the temperature of the substrate 6 to 1500° C. or higher. In this case, it is impossible to use a shower plate made of transparent quartz as the shower plate 20 from the viewpoint of heat resistance, and therefore a shower plate made of carbon needs to be used as the shower plate 20. However, when the shower plate 20 made of carbon is used, radiant light cannot pass through the shower plate 20 and therefore cannot be received by the radiation thermometer 44. On the other hand, in the film-forming apparatus according to this embodiment, the optical path 48 of radiant light emitted from the substrate 6 is secured by providing the tubular member 47, and therefore there is no problem in using the shower plate 20 made of an opaque material such as carbon.

Radiant light from the substrate 6 is focused by the condensing lens of the radiation thermometer 44 on the end face of the optical fiber. Therefore, the inner diameter of the tubular member 47 needs to be equal to or larger than the spot diameter of focused light, and is preferably equal to or larger than 1.2 times the spot diameter of focused light. However, if the inner diameter of the tubular member 47 is too large, there is a fear that the reaction gas 26 enters the inside of the tubular member 47. Therefore, the inner diameter of the tubular member 47 is preferably equal to or less than 2 times the spot diameter of focused light. The film-forming apparatus 50 is configured so that the center of the tubular member 47 can be aligned with the center of the condensing lens as a condensing part.

The tubular member 47 is provided in the chamber 1, and is therefore made of a material having high heat resistance and less likely to emit pollutants during SiC film formation. For example, the tubular member 47 is preferably formed by coating carbon (C) with at least one material selected from the group consisting of SiC, tantalum carbide (TaC), tungsten carbide (WC), and molybdenum carbide (MoC).

Further, in order to reduce the influence of radiant light other than radiant light from the substrate 6, the inner peripheral surface of the tubular member 47 is preferably made of a material having high emissivity and the outer peripheral surface of the tubular member 47 is preferably made of a material having low emissivity. For example, the tubular member 47 is made of carbon (emissivity: 0.85), and only the outer peripheral surface of the tubular member 47 is coated with tantalum carbide (emissivity: 0.17) or molybdenum carbide.

The tubular member 47 extends from the shower plate 20 into the chamber 1 toward the substrate 6. The length L of part of the tubular member 47 extending from the shower plate 20 can be set to an appropriate value. For example, the length L may be 0, that is, the end face of the tubular member 47 on the substrate 6 side may be on the same level as the surface of the shower plate 20 on the substrate 6 side, but part of the tubular member 47 extending from the shower plate 20 preferably has a certain length from the viewpoint of reducing the influence of scattered light caused by crystalline grains adhered to the inside of the chamber 1. However, if the length L is too large, the distance between the end face of the tubular member 47 and the substrate 6 is too short, and therefore there is a fear that the inert gas 25 flowing through the tubular member 47 disturbs the straight flow of the reaction gas 26 near the substrate 6. For this reason, the length L is set so that the influence of the inert gas 25 on the straight flow of the reaction gas 26 can be minimized.

The amount of the inert gas to be supplied to the tubular member 47 is appropriately adjusted in consideration of the amount of the reaction gas 26 to be supplied. More specifically, the amount of the inert gas is preferably set in consideration of the amount of a carrier gas contained in the reaction gas 26 to be supplied.

The film-forming apparatus according to this embodiment may have two or more tubular members. For example, the film-forming apparatus 50 shown in FIG. 1 has only one heater represented by the reference numeral 8, but in some cases, may have, in addition to the heater 8 as an in-heater (a first heater unit), an out-heater (a second heater) for heating the periphery of the substrate 6 in order to more sensitively adjust the temperature of the periphery of the substrate 6. In this case, a radiation thermometer for measuring the temperature of the periphery of the substrate 6 needs to be provided, and therefore a tubular member is preferably provided to secure the optical path of radiant light emitted from the substrate 6 toward this radiation thermometer. This out-heater (second heater) may also be a resistance heating-type heater made of a SiC material.

For example, the film-forming apparatus according to this embodiment may have an in-heater (a first heater) for heating the substrate and an out-heater (a second heater) for heating the periphery of the substrate, as the heating unit. Also the film-forming apparatus may have a first radiation thermometer for measuring a temperature of the center position of the substrate, and a second radiation thermometer for measuring a temperature of the periphery of the substrate. In this case, the film-forming apparatus preferably has a first member that protects the optical path of the radiant light between the substrate and the first radiation thermometer, and a second member that protects the optical path of the radiant light between the substrate and the second radiation thermometer.

Hereinbelow, the film-forming method according to this embodiment will be described with reference to a case where a SiC film is formed using the film-forming apparatus 50 shown in FIG. 1.

### Second Embodiment

First, the substrate 6 is introduced into the chamber 1, and is then placed on the susceptor 7. Then, the substrate 6 placed on the susceptor 7 is rotated at about 50 rpm by rotating the susceptor support 7a and the susceptor 7.

The heater 8 is operated by supplying electric current thereto to heat the substrate 6 by heat emitted from the heater 8. The substrate 6 is gradually heated until the temperature of the substrate 6 reaches a predetermined value in the range of 1500 to 1700° C. at which a SiC film is formed, for example, 1650° C. At this time, an excessive increase in the temperature of the chamber 1 can be prevented by allowing cooling water to flow through the flow paths 3a and 3b provided in the wall of the chamber 1.

After the temperature of the substrate 6 reaches 1650° C., the temperature of the substrate 6 is carefully adjusted to be around 1650° C. by the heater 8. At this time, the temperature of the substrate 6 is measured using the radiation thermometer 44.

Radiant light from the substrate 6 is focused by the condensing lens incorporated in the radiation thermometer 44, and is then transmitted by the optical fiber to the temperature measurement unit. Then, the temperature of the substrate 6 is measured based on the light intensity of radiant light transmitted to the temperature measurement unit. According to this embodiment, the optical path 48 of radiant light between the substrate 6 and the condensing lens is protected with the tubular member 47 to prevent the optical path 48 from being blocked with crystalline grains derived from the reaction gas 26.

Before the measurement of temperature of the substrate 6, the center of the tubular member 47 is previously aligned with the center of the condensing lens as a condensing part. Further, during the supply of the reaction gas 26, the inert gas 25 is introduced from the inert gas supply portion 4 so as to flow downward toward the substrate 6 through the space B and the tubular member 47 in order that the reaction gas 26 does not enter the tubular member 47. Examples of the inert gas include nitrogen (N₂) gas, helium (He) gas, and argon (Ar) gas. Alternatively, hydrogen (H₂) gas may be used instead of the inert gas.

When the substrate 6 is heated to a high temperature, radiant light of continuous wavelength is emitted from the substrate 6 based on Planck's radiation law. Part of the radiant light passes through the tubular member 47 and enters the radiation thermometer 44. More specifically, as described above, radiant light from the substrate 6 is focused by the condensing lens and transmitted by the optical fiber to the temperature measurement unit, and then the temperature of the substrate 6 is measured based on the light intensity of the radiant light.

As described above, by providing the tubular member 47, it is possible to secure the optical path of radiant light between the substrate 6 and the radiation thermometer 44. This makes it possible, even when the substrate 6 needs to be heated to a very high temperature for, for example, epitaxial growth of SiC, to prevent the optical path from being blocked with crystalline grains derived from the reaction gas 26. This makes it possible to accurately measure the temperature of the substrate 6, thereby enabling a high-quality monocrystalline substrate to be obtained.

After it is confirmed that the temperature of the substrate 6 reaches a predetermined value by temperature measurement using the radiation thermometer 44, the number of rotations of the substrate 6 is gradually increased. For example, the number of rotations of the substrate 6 is preferably increased to about 900 rpm.

Further, the reaction gas 26 is supplied from the reaction gas supply portion 14 so as to flow downward through the shower plate 20 onto the substrate 6 placed in the body section 30 of the liner 2. At this time, the flow of the reaction gas 26 is straightened by allowing the reaction gas 26 to pass through the through holes 21 of the shower plate 20 serving as a straightening vane so that the reaction gas 26 flows substantially vertically downward toward the substrate 6 placed under the shower plate 20. That is, the reaction gas 26 forms a so-called vertical flow.

As described above, the reaction gas 26 flows downward toward the substrate 6 in a region from the head section 31 to the body section 30 of the liner 2, and the flow of the reaction gas 26 that flows toward the surface of the substrate 6 is straightened. When the reaction gas 26 reaches the surface of the heated substrate 6, a thermal decomposition reaction or a hydrogen reduction reaction occurs so that a SiC epitaxial film is formed on the surface of the substrate 6.

After the SiC epitaxial film having a predetermined film thickness is formed on the substrate 6, the supply of the reaction gas 26 is stopped. The supply of hydrogen gas as a carrier gas can also be stopped after the completion of formation of the epitaxial film, but may be stopped after it is confirmed that the temperature of the substrate 6 is lower than a predetermined value by measurement using a radiation thermometer (not shown). On the other hand, the supply of the inert gas 25 is stopped after the supply of the reaction gas 26 is stopped in order to prevent the reaction gas 26 from entering the tubular member 47.

After it is confirmed that the substrate 6 has been cooled to a predetermined temperature, the substrate 6 is taken out of the chamber 1.

As described above, by protecting the optical path 48 of radiant light between the substrate 6 and the condensing lens with the tubular member 47, it is possible to prevent the optical path 48 from being blocked with crystalline grains derived from the reaction gas 26. This makes it possible to achieve accurate contactless measurement of the temperature of the substrate 6, thereby enabling a high-quality monocrystalline substrate to be obtained.

It is to be noted that the present invention is not limited to the above embodiment, and various changes may be made without departing from the scope of the present invention.

For example, the above embodiment has been described with reference to a case where a SiC crystalline film is formed using an epitaxial growth apparatus as an example of a film-forming apparatus, but the present invention is not limited thereto. The film-forming apparatus according to the present invention is not particularly limited as long as it can form a film on the surface of a heated substrate placed in a film-forming chamber by supplying a reaction gas into the film-forming chamber.

Further, the above embodiment has been described with reference to a case where a film is formed on a substrate while the substrate is rotated, but the present invention is not limited thereto. The present invention can be applied also to a case where a film is formed on a substrate without rotating the substrate. It is to be noted that all film-forming apparatuses which include the elements of the present invention and which can be appropriately changed in design by those skilled in the art and the shapes of the members of the film-forming apparatuses are included in the scope of the present invention.

The features and advantages of the present invention may be summarized as follows:

According to the first aspect of the present invention, it is possible to provide a film-forming apparatus that can achieve accurate contactless measurement of the temperature of a substrate using a radiation thermometer by providing a member that protects the passage of the optical path of radiant light between the substrate and the radiation thermometer.

According to the second aspect of the present invention, it is possible to provide a film-forming method that can achieve accurate contactless measurement of the temperature of a substrate using a radiation thermometer by protecting the optical path of radiant light emitted from the substrate and received by the radiation thermometer with a tubular member.

Obviously many modifications and variations of the present invention are possible in the light of the above teachings. It is therefore to be understood that within the scope of the appended claims the invention may be practiced otherwise than as specifically described.

1. A film-forming apparatus comprising:
a film-forming chamber in which a substrate is to be placed;
a flow path through which a reaction gas is to be supplied into the film-forming chamber;
a heating unit that heats the substrate;
a radiation thermometer that is provided outside the film-forming chamber to measure a temperature of the substrate by receiving radiant light from the substrate; and
a member that protects the optical path of the radiant light between the substrate and the radiation thermometer.

2. The film-forming apparatus according to claim 1, further comprising a flow path that is provided separately from the flow path of a reaction gas to supply an inert gas or hydrogen gas to the member.

3. The film-forming apparatus according to claim 1, wherein the member is a tubular member having an inner peripheral surface and an outer peripheral surface made of a material having a lower emissivity than the inner peripheral surface.

4. The film-forming apparatus according to claim 1, wherein the heating unit has a first heater for heating the substrate and a second heater for heating the periphery of the substrate;
the radiation thermometer has a first radiation thermometer for measuring a temperature of the center position of the substrate, and a second radiation thermometer for measuring a temperature of the periphery of the substrate;
further comprising: a first member that protects the optical path of the radiant light between the substrate and the first radiation thermometer; and
a second member that protects the optical path of the radiant light between the substrate and the second radiation thermometer.

5. The film-forming apparatus according to claim 3, wherein the outer peripheral surface is comprised of carbon, and the inner peripheral surface is comprised of tantalum carbide or molybdenum carbide.

6. A film-forming method comprising introducing a reaction gas into a film-forming chamber, in which a substrate is being heated, to perform film formation, wherein a radiation thermometer is provided outside the film-forming chamber, an optical path of radiant light emitted from the substrate and received by the radiation thermometer is protected with a tubular member, and a temperature of the substrate is measured based on an light intensity of the radiant light received by the radiation thermometer.

7. The film-forming method according to claim 4, further comprising introducing an inert gas or hydrogen gas into the tubular member through a flow path provided separately from a flow path of the reaction gas.

8. The film-forming method according to claim 6, wherein the outer peripheral of the tubular member is comprised of a material having a lower emissivity than the inner peripheral surface.

9. The film-forming method according to claim 6, wherein a reaction gas is introduced into a film-forming chamber, in which a substrate is being rotated and heated, to perform film formation
